(19) United States
(12) Patent Application Publication
(10) Pub. No.: US 2013/0270255 A1
(43) Pub. Date: Oct. 17, 2013

(54) Silicon-Based Cooling Package With Preheating Capability For Compact Heat-Generating Devices

(71) Applicants: Gerald Ho Kim, Carlsbad, CA (US); Jay Eunjae Kim, Issaquah, WA (US)

(72) Inventors: Gerald Ho Kim, Carlsbad, CA (US); Jay Eunjae Kim, Issaquah, WA (US)

(21) Appl. No.: 13/863,349

(22) Filed: Apr. 15, 2013

Related U.S. Application Data
(60) Provisional application No. 61/625,493, filed on Apr. 17, 2012.

(51) Int. Cl. H05K 7/20; H05B 1/02

(52) U.S. Cl. CPC H05K 7/2039; H05B 1/0288
USPC 219/494; 165/64

(57) ABSTRACT

A silicon-based thermal energy transfer apparatus that aids dissipation of thermal energy from a heat-generating device is described. In one aspect, the apparatus comprises a silicon-based cooling device configured to receive the heat-generating device and at least one heating element disposed on the silicon-based cooling device. The at least one heating element is configured to maintain a temperature of at least a first region of the silicon-based cooling device in a predetermined condition when the heat-generating device is deactivated.

### CROSS-REFERENCE TO RELATED PATENT APPLICATION

The present application claims the priority benefit of U.S. Provisional Patent Application No. 61/625,493, filed Apr. 17, 2012, which is hereby incorporated by reference in its entirety.

### BACKGROUND

1. Technical Field

The present disclosure generally relates to the field of transfer of thermal energy and, more particularly, to the removal of thermal energy from compact heat-generating devices.

2. Description of the Related Art

Compact heat-generating devices, such as light-emitting diodes (LEDs), laser diodes, microprocessors, integrated circuits and the like, generate thermal energy, or heat, when in operation. Regardless of which type of heat-generating device the case may be, heat generated by a compact heat-generating device must be removed or dissipated from the compact heat-generating device in order to achieve optimum performance of the compact heat-generating device and keep its temperature within a safe operating range. With the form factor of compact heat-generating devices and the applications they are implemented in becoming ever smaller, resulting in high heat density, it is imperative to effectively dissipate the high-density heat generated in an area of small footprint to ensure safe and optimum operation of compact heat-generating devices operating under such conditions.

Many metal-based water-cooled and air-cooled cooling packages have been developed for use in compact packages to dissipate heat generated by the various types of compact heat-generating devices mentioned above. For instance, heat exchangers and heat pipes made of a metallic material with high thermal conductivity, such as copper, silver, aluminum or iron, are commercially available. However, most metal-based heat exchangers and heat pipes experience issues of oxidation, corrosion and/or crystallization after long periods of operation. Such fouling factors significantly reduce the heat transfer efficiency of metal-based heat exchangers and heat pipes. Other problems associated with the use of metal-based cooling packages include, for example, issues with overall compactness of the package, corrosion of the metallic material in water-cooled applications, difficulty in manufacturing, and so on. With increasing demand for high power density in small form factor, there is a need for a compact cooling package for compact heat-generating devices with fewer or none of the aforementioned issues.

Additionally, some heat-generating devices need to operate in a certain temperature range in order to perform optimally or produce results that are within a given specification. In the case of laser diodes, for example, the wavelength of light emitted by a laser diode is affected by the temperature the laser diode is at. Before the laser diode is turned on to be in operation, the laser diode may be at a relatively lower temperature than the temperature the laser diode is at when having been in operation for a period of time. That is, before the laser diode reaches a certain temperature the wavelength of the light emitted by the laser diode may not be useful.

### SUMMARY

Various embodiments of a silicon-based thermal energy transfer apparatus that aids dissipation of thermal energy from a heat-generating device are provided.

In one aspect, the silicon-based thermal energy transfer apparatus may comprise: a silicon-based cooling device configured to receive the heat-generating device; and at least one heating element disposed on the silicon-based cooling device and configured to maintain a temperature of at least a first region of the silicon-based cooling device in a predetermined condition, when the heat-generating device is deactivated, with the at least one heating element activated.

In some embodiments, the at least one heating element may comprise at least one thin-film heater. In other embodiments, the at least one heating element may comprise at least one thick-film heater.

In some embodiments, the silicon-based cooling device may comprise components made of single-crystal silicon.

In some embodiments, the at least one heating element may be configured to maintain the temperature of at least the first region of the silicon-based cooling device above a first temperature threshold when the heat-generating device is received in the silicon-based cooling device and not activated.

In some embodiments, the silicon-based cooling device may comprise first and second silicon-based fin portions and a silicon-based base portion having a first primary surface on which the first and second fin portions are disposed. The first and second fin portions may longitudinally extend from the first primary surface of the base portion. When the heat-generating device is received in the silicon-based cooling device, the heat-generating device may be received between a first primary surface of the first fin portion and a first primary surface of the second fin portion.

In some embodiments, the first primary surface of the first fin portion may comprise a recess in which the heat-generating device is received.

In some embodiments, the at least one heating element may comprise a first heating element disposed on a second primary surface of the second fin portion that is opposite the first primary surface of the second fin portion. Alternatively or additionally, the at least one heating element may comprise a first heating element disposed on a second primary surface of the first fin portion that is opposite the first primary surface of the first fin portion. Alternatively or additionally, the at least one heating element may comprise a first heating element disposed on the first primary surface of the base portion.

In some embodiments, the base portion may further comprise at least a first electrical pad and a second electrical pad on the first primary surface of the base portion. The at least one heating element may further comprise first and second electrically-conductive lead lines extending from the at least one heating element to the first and second electrical pads through which electrical power is provided to the at least one heating element.

In some embodiments, the base portion may further comprise at least a first via and a second via that traverse the base portion and connect the first primary surface and a second primary surface of the base portion that is opposite the first primary surface. The at least one heating element may further comprise first and second electrically-conductive lead lines extending from the at least one heating element to the first and second vias through which electrical power is provided to the at least one heating element.

In some embodiments, the base portion may further comprise first and second grooves each having a generally V-shaped longitudinal cross section such that the first and second fin portions are interlockingly received in the first and second grooves respectively. At least an edge of the first fin portion may be generally V-shaped and received in the first groove. At least an edge of the second fin portion may be generally V-shaped and received in the second groove.

In some embodiments, the apparatus may further comprise a temperature sensing element coupled to sense a temperature of at least a second region of the silicon-based cooling device. The temperature sensing element may cause the at least one heating element to be activated when the sensed temperature of at least the second region of the silicon-based cooling device satisfies a first condition. The temperature sensing element may cause the at least one heating element to be deactivated when the sensed temperature of at least the second region of the silicon-based cooling device satisfies a second condition.

In some embodiments, the first condition may comprise the sensed temperature of at least the second region of the silicon-based cooling device being below a second temperature threshold, and the second condition may comprise the sensed temperature of at least the second region of the silicon-based cooling device being above the second temperature threshold.

In some embodiments, the apparatus may further comprise the heat-generating device received in the silicon-based cooling device with at least two sides of the heat-generating device in contact with the silicon-based cooling device.

In some embodiments, the heat-generating device may comprise a laser diode having a first primary surface and a second primary surface. The first primary surface and the second primary surface may be in contact with the silicon-based cooling device to allow transfer of thermal energy between the laser diode and the silicon-based cooling device by conduction through the first and second primary surfaces of the laser diode.

In another aspect, a silicon-based thermal energy transfer apparatus may comprise a silicon-based cooling device and at least one heating element disposed on the silicon-based cooling device. The silicon-based cooling device may comprise a base portion and first and second fin portions. The base portion, made of silicon, may have a first primary surface. The first and second fin portions, made of silicon, may extend longitudinally from the first primary surface of the base portion. The first fin portion may include a first primary surface that faces the second fin portion and that is configured to be in contact with the heat-generating device when the heat-generating device is received in the cooling device. The first fin portion may further include a second primary surface opposite the first primary surface of the first fin portion. The second fin portion may include a first primary surface that faces the first fin portion and that is configured to be in contact with the heat-generating device when the heat-generating device is received in the cooling device. The second fin portion may further include a second primary surface opposite the first primary surface of the second fin portion. The at least one heating element may be configured to maintain a temperature of at least a first region of the silicon-based cooling device in a predetermined condition, when the heat-generating device is deactivated, with the at least one heating element activated.

In some embodiments, the at least one heating element may comprise a thin-film resistive heater disposed on the second primary surface of the base portion.

In some embodiments, the at least one heating element may comprise a thick-film resistive heater disposed on the second primary surface of the base portion.

This summary is provided to introduce concepts relating to a silicon-based thermal energy transfer apparatus that aids dissipation of thermal energy from a heat-generating device. Some embodiments of the silicon-based thermal energy transfer apparatus are further described below in the detailed description. This summary is not intended to identify essential features of the claimed subject matter, nor is it intended for use in determining the scope of the claimed subject matter.

### BRIEF DESCRIPTION OF THE DRAWINGS

The accompanying drawings are included to provide a further understanding of the disclosure, and are incorporated in and constitute a part of the present disclosure. The drawings illustrate embodiments of the disclosure and, together with the description, serve to explain the principles of the disclosure. It is appreciable that the drawings are not necessarily in scale as some components may be shown to be out of proportion than the size in actual implementation in order to clearly illustrate the concept of the present disclosure.

FIG. 1 is a three-dimensional view of a silicon-based thermal energy transfer apparatus that aids dissipation of thermal energy from a heat-generating device in accordance with a first embodiment of the present disclosure.

FIG. 2 is an exploded view of the silicon-based thermal energy transfer apparatus of FIG. 1 in accordance with an embodiment of the present disclosure.

FIG. 3 is a top view of the silicon-based thermal energy transfer apparatus of FIG. 1 in accordance with an embodiment of the present disclosure.

FIG. 4 is a front view of the silicon-based thermal energy transfer apparatus of FIG. 1 in accordance with an embodiment of the present disclosure.

FIG. 5 is a cross-sectional view of the silicon-based thermal energy transfer apparatus of FIG. 4 along line A-A in accordance with an embodiment of the present disclosure.

FIG. 6 is a bottom view of the silicon-based thermal energy transfer apparatus of FIG. 1 in accordance with an embodiment of the present disclosure.

FIG. 7A is a front view of the silicon-based thermal energy transfer apparatus of FIG. 1 showing the heating element in operation.

FIG. 7B is a front view of the silicon-based thermal energy transfer apparatus of FIG. 1 showing the heater not in operation when the heat-generating device is generating heat.

### DETAILED DESCRIPTION OF PREFERRED EMBODIMENTS

### Overview

The present disclosure describes embodiments of a silicon-based thermal energy transfer apparatus that aids dissipation of thermal energy from a heat-generating device. The disclosed silicon-based thermal energy transfer apparatus is capable of preheating the heat-generating device to maintain the temperature of the heat-generating device in a predetermined condition before the heat-generating device is activated, e.g., turned on, to be put in operation. This way, for those heat-generating devices that need to operate in a certain temperature range in order to perform optimally or produce results that are within a given specification, there is no idle time between the time the heat-generating device is activated and the time the heat-generating device begins to perform optimally or produces results that are within specification since the heat-generating device is already at a temperature that is within a desired range for optimal performance.

In the case of the heat-generating device being a laser diode, the disclosed silicon-based thermal energy transfer apparatus can preheat the temperature of the laser diode to be within a predetermined temperature range before the laser diode is activated. As the temperature of a laser diode affects the wavelength of the light emitted by the laser diode, embodiments of the present disclosure advantageously allow the laser diode to emit light having a desired wavelength as soon as the laser diode is activated.

While aspects of the disclosed embodiments and techniques may be implemented in any number of different applications, for the purpose of illustration the disclosed embodiments are described in context of the following exemplary configurations.

### Illustrative Scenario

A heating element, e.g., a thin-film resistive heater or a heat pad, is placed at the bottom of a silicon-based thermal energy transfer apparatus along with electrodes. The electrodes are connected to a printed circuit board (PCB) as anode and cathode, and the heat pad is soldered to the PCB. The electrodes are also electrically connected to a heat-generating device, e.g., a laser diode, through via-holes. The electrodes and the heat pad have a function of transferring heat into the PCB with the PCB acting as a heat sink.

The heat pad may be a metal pad functioning as a resistor. The resistor may be made with a thin or thick film or embedded into a silicon bulk material. The heat pad may be connected to a power supply separate from a laser diode power supply.

When the laser diode is turned on, the operating wavelength of the laser diode at the instant may be shorter than the normal operating wavelength. This is a normal behavior of laser diode operation and it usually takes a few seconds to minutes before the laser diode reaches a normal operating temperature, and the wavelength of the light emitted from the laser diode at such normal operating temperature would be the normal operating wavelength. In order to quickly bring and maintain a proper operating wavelength of the light emitted from the laser diode, a special device or mechanism has to be added or developed for low or high power laser diode package.

For this reason an electrically-controlled heat pad is placed between the laser diode and the heat sink, and in the present disclosure that would be somewhere on the silicon-based thermal energy transfer apparatus or laser diode cooling package structure. The heat pad is used to gate a heat flow from the laser diode to the heat sink, such as a metal PCB or copper heat sink. In addition, to shorten the turn-on time of the laser diode, the heat pad is turned on early to heat up the cooling package structure, and therefore the laser diode, so that the laser diode can reach its normal operating temperature quickly. The heat pad is also used to maintain the operating temperature of the laser diode. For instance, the operating temperature of the laser diode may be increasing then the heat pad may provide a path for heat dissipation from the laser diode to the heat sink, thereby lowering the temperature of the laser diode. In the other case, the heat-pad will increase the head loading so that the laser diode can increase the operating temperature. This mechanism is needed to maintain the operating wavelength of laser diode by maintaining a constant temperature and help to shorten a turn-on time.

The above-described device or control method is also used to adjust a temperature change caused by an environmental temperature fluctuation. It is hard to change the heat-loading of the laser diode to maintain an operating wavelength and the heat pad is needed to adjust for the temperature fluctuation.

The disclosed techniques provide a novel silicon-based cooling package structure and method of using a heat pad to gate a heat flow to maintain a constant temperature of the laser diode.

### Illustrative Embodiments

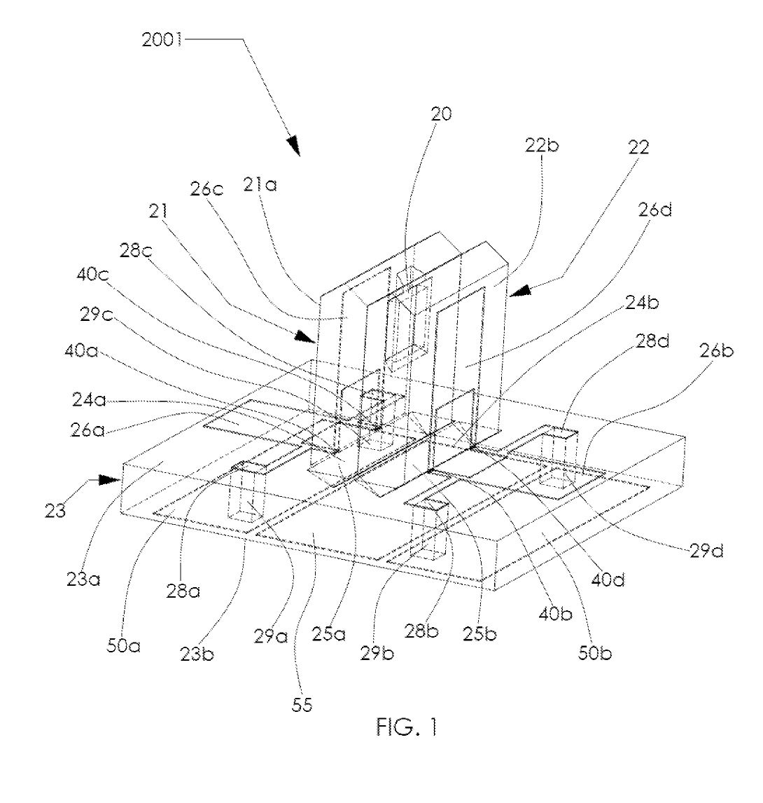

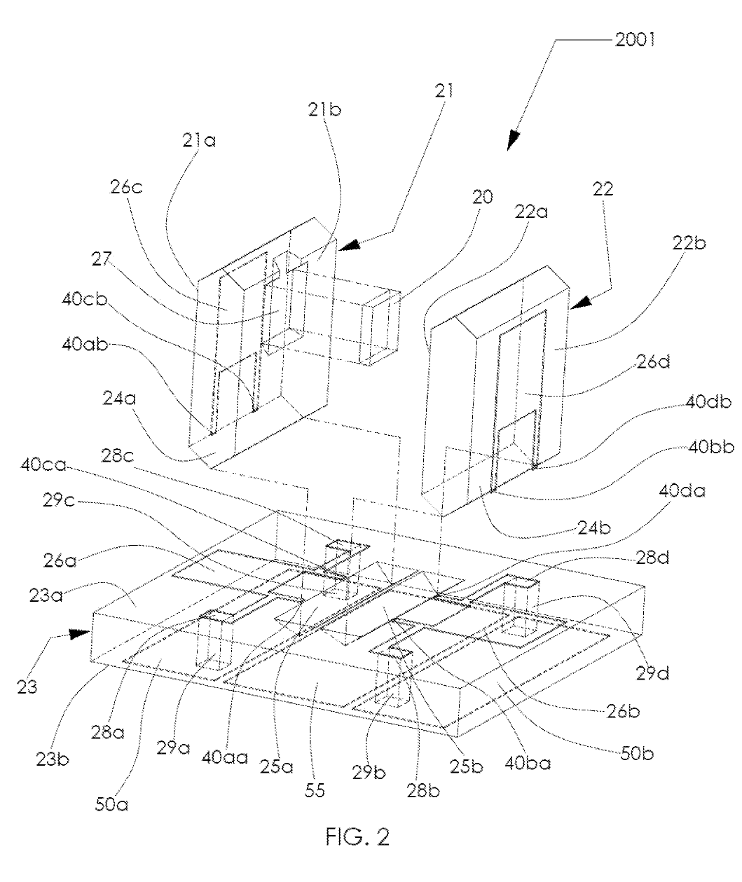

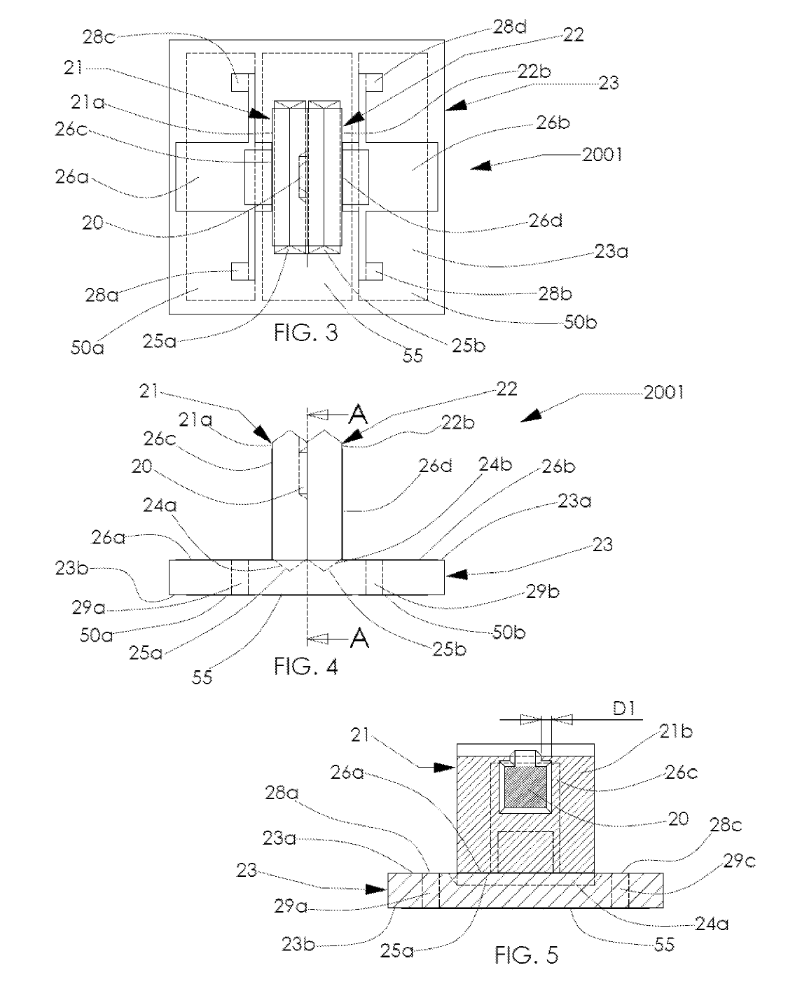

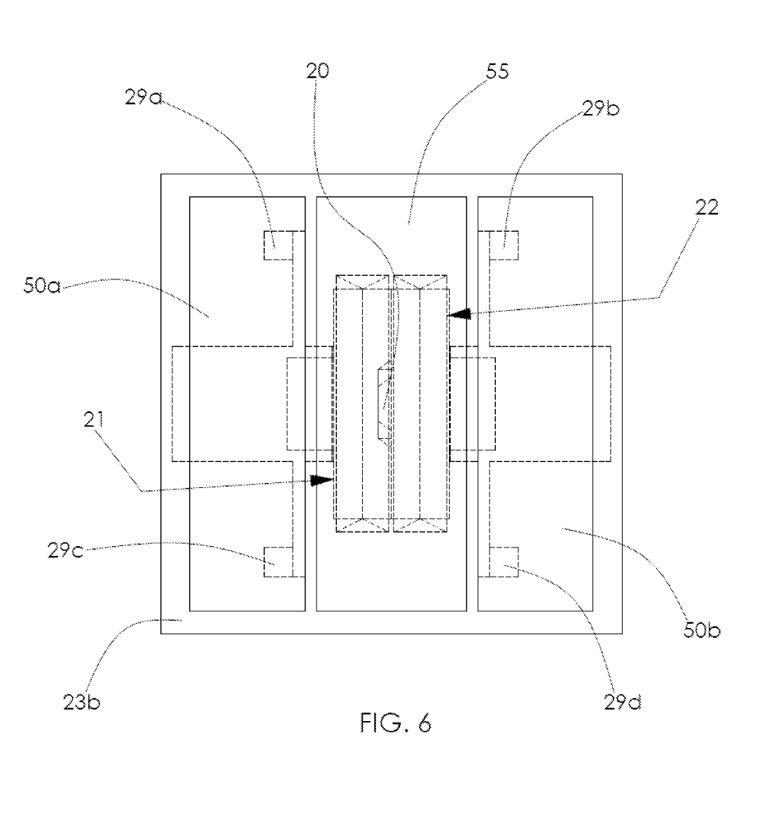

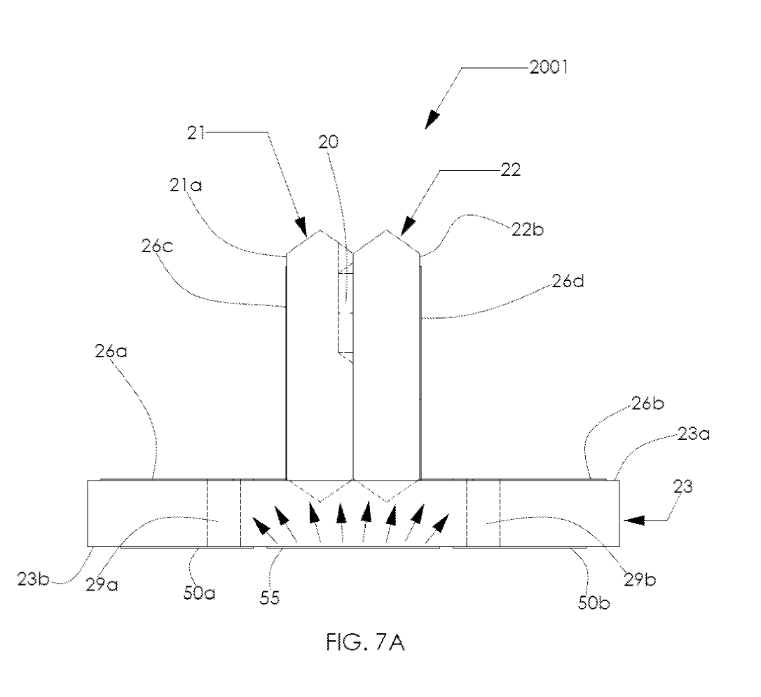

FIGS. 1-6 illustrate various views of a silicon-based thermal energy transfer apparatus in accordance with an embodiment of the present disclosure. The apparatus comprises a silicon-based cooling device 2001 that is configured to receive a heat-generating device 20. The apparatus further comprises a heating element 55 disposed on the silicon-based cooling device 2001. Additionally or alternatively, the apparatus may also comprise at least one heating element 26, represented by multiple heating elements 26a, 26b, 26c and 26d in FIGS. 1-6, disposed on the silicon-based cooling device 2001. Although the illustrated embodiment of FIGS. 1-6 show one heating element 55 and four heating elements 26a, 26b, 26c and 26d, in other embodiments the silicon-based thermal energy transfer apparatus may have a different number, whether fewer or more, of the heating element 55 and the at least one heating elements 26.

In some embodiments, each of the heating element 55 and the at least one heating element 26 comprises at least one thin-film heater made of a suitable material and deposited on one or more surfaces of the silicon-based cooling device 2001 by a suitable method presently known or to be developed in the future. For example, the at least one heating element 26 may be a resistive heater made with a thin film of titanium. Heat will be generated when an electric current flows through the thin film of metal. In some embodiments, a thin layer of metal pattern can be first deposited on the silicon-based cooling device 2001 and then a thin layer of glass layer for insulation can be deposited on the thin layer of metal pattern, then a solder pattern is provided.

In other embodiments, each of the heating element 55 and the at least one heating element 26 comprises at least one thick-film heater made of a suitable material and deposited on one or more surfaces of the silicon-based cooling device 2001 by a suitable method presently known or to be developed in the future. For example, the at least one heating element 26 may be a resistive heater made with a thick film of MgO₂.

The silicon-based cooling device 2001 comprises a first silicon-based fin portion 21, a second silicon-based fin portion 22, and a silicon-based base portion 23 having a first primary surface 23a (e.g., the top surface), on which the first and second fin portions 21, 22 are disposed, and a second primary surface 23b (e.g., the bottom surface) opposite to the first primary surface 23a. The first and second fin portions 21, 22 longitudinally extend from the first primary surface 23a of the base portion 23. The first fin portion 21 has a first primary surface 21a and a second primary surface 21b that is opposite the first primary surface 21a. The second fin portion 22 has a first primary surface 22a and a second primary surface 22b that is opposite the first primary surface 22a. The first primary surface 21a of the first fin portion 21 and the first primary surface 21b of the second fin portion 22 face toward one another and are generally parallel to one another. When the heat-generating device 20 is received in the silicon-based cooling device 2001, the heat-generating device 20 is received between the first primary surface 21a of the first fin portion 21 and the first primary surface 22a of the second fin portion 22.

In some embodiments, one or more of the first silicon-based fin portion 21, the second silicon-based fin portion 22, and the silicon-based base portion 23 are made of single-crystal silicon.

In some embodiments, the first primary surface 21a of the first fin portion 21 comprises a recess 27 that is shaped and dimensioned to receive the heat-generating device 20. When the heat-generating device 20 is received in the silicon-based cooling device 2001 and, more specifically, between the first fin portion 21 and the second fin portion 22 of the silicon-based cooling device 2001, the heat-generating device 20 is snugly fitted in the recess 27.

In some embodiments, the heating element 55 is disposed on the second primary surface 23b of the silicon-based base portion 23. For example, the heating element 55 may be placed directly below the first fin portion 21 and the second fin portion 22 so that heat generated by the heating element 55 can flow across the base portion 23 to the first and second fin portions 21, 22 through which the heat is conducted to the heat-generating device 20 when the heat-generating device 20 is deactivated, i.e., turned off, or has just been activated, i.e., turned on, but the temperature of which is still below a first temperature threshold.

In some embodiments, the at least one heating element 26 comprises the heating element 26d disposed on the second primary surface 22b of the second fin portion 22. Alternatively or additionally, the at least one heating element 26 comprises the heating element 26c disposed on the second primary surface 21b of the first fin portion 21. Alternatively or additionally, the at least one heating element 26 comprises the heating element 26a and/or the heating element 26b disposed on the first primary surface 23a of the base portion 23.

The heating element 55, and each of the at least one heating element 26 if any, is electrically powered to produce heat. Accordingly, the heating element 55, and each of the at least one heating element 26, is connected to a power source, such as a direct current (DC) power source. This may be accomplished through electrical pads or vias on the base portion 23.

In some embodiments, the base portion 23 further comprises a first electrical pad 50a and a second electrical pad 50b disposed on the second primary surface 23b of the base portion 23. The heating element 55 is connected to the electrical pads 50a, 50b by electrically-conductive lead lines.

In some embodiments, the base portion 23 further comprises at least a third electrical pad 28a or 28b and a fourth electrical pad 28c or 28d disposed on the first primary surface 23a of the base portion 23. In these embodiments, the at least one heating element 26 further comprises electrically-conductive lead lines, such as lead lines 40aa and 40ca for heating element 26a, lead lines 40ab and 40cb for heating element 26c, lead lines 40bb and 40db for heating element 26d, and lead lines 40ba and 40da for heating element 26b as shown in FIGS. 1-5. The lead lines extend from the at least one heating element 26 to the third electrical pad 28a or 28b and the fourth electrical pad 28c or 28d through which electrical power is provided to the at least one heating element 26. As shown in FIGS. 1-5, lead lines 40aa and 40ca connect heating element 26a to electrical pads 28a and 28c, lead lines 40ba and 40da connect heating element 26b to electrical pads 28b and 28d, lead lines 40ab and 40cb connect heating element 26c to electrical pads 28a and 28c, and lead lines 40bb and 40 db connect heating element 26d to electrical pads 28b and 28d.

Alternatively, in some embodiments, the base portion 23 further comprises at least a first via 29a or 29b and a second via that 29c or 29d that traverse the base portion 23 and connect the first primary surface 23a of the base portion 23 and the second primary surface 23b of the base portion 23. The first and second electrical pads 50a, 50b may be electrically coupled to the third and fourth electrical pads 28a, 28b, 28c, 28d by the vias 29a, 29b, 29c, 29d, respectively.

In some embodiments, the at least one heating element 26 may further comprise additional electrically-conductive lead lines, such as lead lines 40aa and 40ca for heating element 26a, lead lines 40ab and 40cb for heating element 26c, lead lines 40bb and 40 db for heating element 26d, and lead lines 40ba and 40da for heating element 26b as shown in FIGS. 1-5. The lead lines extend from the at least one heating element 26 to the first via 29a or 29b and the second via 29c or 29d through which electrical power is provided to the at least one heating element 26. As shown in FIGS. 1-5, lead lines 40aa and 40ca connect heating element 26a to vias 29a and 29c, lead lines 40ba and 40da connect heating element 26b to vias 29b and 29d, lead lines 40ab and 40cb connect heating element 26c to vias 29a and 29c, and lead lines 40bb and 40 db connect heating element 26d to vias 29b and 29d.

In some embodiments, the base portion 23 further comprises a first groove 25a and a second groove 25b each having a generally V-shaped longitudinal cross section. At least an edge 24a of the first fin portion 21 is generally V-shaped to be received in the first groove 25a. At least an edge 24b of the second fin portion 22 is generally V-shaped to be received in the second groove 25b. Accordingly, the first fin portion 21 and the second fin portion 22 are interlockingly received in the first and second grooves 25a, 25b of the base portion 23, respectively.

Since thermal energy, or heat, is ether transferred from the heat-generating device 20 to the silicon-based cooling device 2001 (e.g., when the heat-generating device 20 is activated and producing heat) or from the silicon-based cooling device 2001 to the heat-generating device 20 (e.g., when the heat-generating device 20 is deactivated with the heating element 55 and/or the at least one heating element 26 activated), temperature of the silicon-based cooling device 2001 more or less reflects temperature of the heat-generating device 20. Thus, the temperature of the heat-generating device 20 can be indirectly measured by measuring the temperature of a select region of the silicon-based cooling device 2001. Accordingly, the activation and deactivation of the heating element 55 and/or the at least one heating element 26 can be controlled based on the temperature of the select region of the silicon-based cooling device 2001 which reflects the temperature of the heat-generating device 20.

In some embodiments, the apparatus further comprises a temperature sensing element (not shown) coupled to sense a temperature of at least a second region of the silicon-based cooling device 2001. The temperature sensing element can cause the heating element 55 and the at least one heating element 26 to be activated when the sensed temperature of at least the second region of the silicon-based cooling device 2001 satisfies a first condition, such as being below a second temperature threshold. The temperature sensing element can cause the heating element 55 and the at least one heating element 26 to be deactivated when the sensed temperature of at least the second region of the silicon-based cooling device 2001 satisfies a second condition, such as being above the second temperature threshold. In some embodiments, the temperature sensing element may be a thermistor.

In some embodiments, the apparatus further comprises the heat-generating device 20 received in the silicon-based cooling device 2001 with at least two sides of the heat-generating device 20 in contact with the silicon-based cooling device 2001. The heat-generating device 20 may comprise a laser diode having a first primary surface and a second primary surface that are in contact with the first and second fin portions 21, 22 of the silicon-based cooling device 2001 to allow transfer of thermal energy between the laser diode and the silicon-based cooling device 2001 by conduction through the first and second primary surfaces of the laser diode.

### Illustrative Operation

When the heat-generating device 20 is received in the silicon-based cooling device 2001 of the apparatus, the heating element 55 and/or the at least one heating element 26 can maintain a temperature of at least a first region of the silicon-based cooling device 2001, such as the region surrounding and in contact with the heat-generating device 20, in a predetermined condition, e.g., above a first temperature threshold or within a desired temperature range, when the heat-generating device 20 is deactivated (e.g., turned off) by having the heating element 55 and/or the at least one heating element 26 activated (e.g., generating heat). For example, when the heat-generating device 20 is a laser diode, the first temperature threshold may be the lowest temperature of a temperature range within which the laser diode can emit light having a desired wavelength. Alternatively, the first temperature threshold may be a temperature that falls within the temperature range within which the laser diode can emit light having a desired wavelength.

In embodiments where the apparatus further comprises a temperature sensing element, such as a thermistor for example, the heating element 55 and the at least one heating element 26 can be controlled to be switched on and off, activated and deactivated, based on whether the temperature sensed by the temperature sensing element is below or above a second temperature threshold. As the temperature sensing element senses the temperature of the region of the silicon-based cooling device 2001 to which the temperature sensing device is coupled, the second temperature threshold can be set to be a temperature the same as or different than the first temperature threshold. In any case, the second temperature threshold can be set to be somewhere in the optimal operating temperature range within which the heat-generating device 20 can emit light having a desired wavelength.

When the sensed temperature is below the second temperature threshold, indicative of the heat-generating device 20 being deactivated and not generating heat, the heating element 55 and/or the at least one heating element 26 will be activated to generate heat to maintain the temperature of the region of the silicon-based cooling device 2001 in the vicinity of the heating element 55 and the at least one heating element 26 within a predetermined temperature range. As the heat-generating device 20 is not generating heat, in this case thermal energy will transfer from the silicon-based cooling device 2001 to the heat-generating device 20. This, in turn, maintains the temperature of the heat-generating device 20 to be within a predetermined temperature range. When the sensed temperature is above the second temperature threshold, indicative of the heat-generating device 20 being activated and generating heat, the heating element 55 and the at least one heating element 26 will be deactivated to cease generating heat.

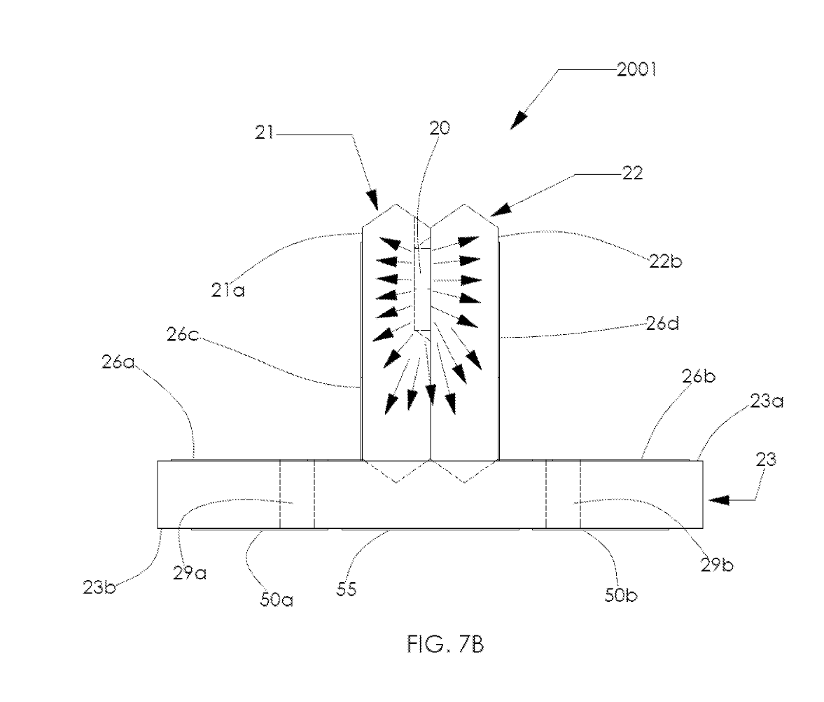

FIG. 7A is a front view of the silicon-based thermal energy transfer apparatus of FIG. 1 showing the heating element in operation. This may be a time when the heat-generating device 20, e.g., a laser diode, is not activated or has just been activated but has not reached a certain temperature. As shown in FIG. 7A, when the heating element 55 is activated and generating heat, the heat generated by the heating element 55 is conducted from the second primary surface 23b of the silicon-based base portion 23 to the rest of the base portion 23. The heat, in turn, is transferred to the heat-generating device 20 to keep the heat-generating device 20 at a given temperature.

FIG. 7B is a front view of the silicon-based thermal energy transfer apparatus of FIG. 1 showing the heater not in operation when the heat-generating device 20 is generating heat. This may be a time when the heat-generating device 20 has been activated and generating heat for a while and is operating in its normal operating temperature range. The heating element 55 may be deactivated at this time as there is no need to supply heat to the heat-generating device 20 to maintain its temperature. The heating element 55, however, may serve as a gate or path to transfer the heat dissipated from the heat-generating device 20 to a heat sink, e.g., a PCB or a piece of metal that the heating element 55 is in contact with (not shown).

### CONCLUSION

The above-described techniques pertain to temperature control of a heat-generating device that is being cooled by a silicon-based thermal energy transfer apparatus. Although the techniques have been described in language specific to certain applications, it is to be understood that the appended claims are not necessarily limited to the specific features or applications described herein. Rather, the specific features and applications are disclosed as exemplary forms of implementing such techniques. For instance, although the techniques have been described in the context of preheating a laser diode before the laser diode is activated for operation, the techniques may be applied in any other suitable context.

What is claimed is:

1. A silicon-based thermal energy transfer apparatus that aids dissipation of thermal energy from a heat-generating device, the apparatus comprising:
a silicon-based cooling device configured to receive the heat-generating device; and
at least one heating element disposed on the silicon-based cooling device and configured to maintain a temperature of at least a first region of the silicon-based cooling device in a predetermined condition.

2. The apparatus of claim 1, wherein the at least one heating element comprises at least one thin-film heater.

3. The apparatus of claim 1, wherein the at least one heating element comprises at least one thick-film heater.

4. The apparatus of claim 1, wherein the silicon-based cooling device comprises components made of single-crystal silicon.

5. The apparatus of claim 1, wherein the at least one heating element configured to maintain a temperature of at least a first region of the silicon-based cooling device in a predetermined condition comprises the at least one heating element configured to maintain the temperature of at least the first region of the silicon-based cooling device above a first temperature threshold when the heat-generating device is received in the silicon-based cooling device and not activated.

6. The apparatus of claim 1, wherein the silicon-based cooling device comprises:
first and second silicon-based fin portions; and
a silicon-based base portion having a first primary surface on which the first and second fin portions are disposed such that:
the first and second fin portions longitudinally extend from the first primary surface of the base portion, and
when the heat-generating device is received in the silicon-based cooling device, the heat-generating device is received between a first primary surface of the first fin portion and a first primary surface of the second fin portion.

7. The apparatus of claim 6, wherein the first primary surface of the first fin portion comprises a recess in which the heat-generating device is received.

8. The apparatus of claim 6, wherein the at least one heating element comprises a first heating element disposed on a second primary surface of the second fin portion that is opposite the first primary surface of the second fin portion.

9. The apparatus of claim 6, wherein the at least one heating element comprises a first heating element disposed on a second primary surface of the first fin portion that is opposite the first primary surface of the first fin portion.

10. The apparatus of claim 6, wherein the at least one heating element comprises a first heating element disposed on the second primary surface of the base portion.

11. The apparatus of claim 6, wherein the base portion further comprises:
at least a first electrical pad and a second electrical pad on the first primary surface of the base portion, wherein the at least one heating element further comprises first and second electrically-conductive lead lines extending from the at least one heating element to the first and second electrical pads through which electrical power is provided to the at least one heating element.

12. The apparatus of claim 6, wherein the base portion further comprises:
at least a first via and a second via that traverse the base portion and connect the first primary surface and a second primary surface of the base portion that is opposite the first primary surface, wherein the at least one heating element further comprises first and second electrically-conductive lead lines extending from the at least one heating element to the first and second vias through which electrical power is provided to the at least one heating element.

13. The apparatus of claim 6, wherein the base portion further comprises:
first and second grooves each having a generally V-shaped longitudinal cross section such that the first and second fin portions are interlockingly received in the first and second grooves respectively, wherein at least an edge of the first fin portion is generally V-shaped and received in the first groove, and wherein at least an edge of the second fin portion is generally V-shaped and received in the second groove.

14. The apparatus of claim 1, further comprising:
a temperature sensing element coupled to sense a temperature of at least a second region of the silicon-based cooling device such that:
the temperature sensing element causes the at least one heating element to be activated when the sensed temperature of at least the second region of the silicon-based cooling device satisfies a first condition, and
the temperature sensing element causes the at least one heating element to be deactivated when the sensed temperature of at least the second region of the silicon-based cooling device satisfies a second condition.

15. The apparatus of claim 14, wherein the first condition comprises the sensed temperature of at least the second region of the silicon-based cooling device is below a second temperature threshold, and wherein the second condition comprises the sensed temperature of at least the second region of the silicon-based cooling device is above the second temperature threshold.

16. The apparatus of claim 1, further comprising:
the heat-generating device received in the silicon-based cooling device with at least two sides of the heat-generating device in contact with the silicon-based cooling device.

17. The apparatus of claim 16, wherein the heat-generating device comprises a laser diode having a first primary surface and a second primary surface, and wherein the first primary surface and the second primary surface are in contact with the silicon-based cooling device to allow transfer of thermal energy between the laser diode and the silicon-based cooling device by conduction through the first and second primary surfaces of the laser diode.

18. A silicon-based thermal energy transfer apparatus that aids dissipation of thermal energy from a heat-generating device, the apparatus comprising:
a silicon-based cooling device that comprises:
a base portion made of silicon and having a first primary surface and a second primary surface opposite the first primary surface; and
first and second fin portions made of silicon and extending longitudinally from the first primary surface of the base portion, the first fin portion having a first primary surface that faces the second fin portion and that is configured to be in contact with the heat-generating device when the heat-generating device is received in the cooling device, the first fin portion further having a second primary surface opposite the first primary surface of the first fin portion, the second fin portion having a first primary surface that faces the first fin portion and that is configured to be in contact with the heat-generating device when the heat-generating device is received in the cooling device, the second fin portion further having a second primary surface opposite the first primary surface of the second fin portion; and
at least one heating element disposed on the silicon-based cooling device and configured to maintain a temperature of at least a first region of the silicon-based cooling device in a predetermined condition.

19. The apparatus of claim 18, wherein the at least one heating element comprises a thin-film resistive heater disposed on the second primary surface of the base portion.

20. The apparatus of claim 18, wherein the at least one heating element comprises a thick-film resistive heater disposed on the second primary surface of the base portion.
